(19) United States
(12) Patent Application Publication
(10) Pub. No.: US 2024/0355577 A1
(43) Pub. Date: Oct. 24, 2024

(54) CHARGED-PARTICLE BEAM DEVICE FOR DIFFRACTION ANALYSIS

(71) Applicant: ELDICO SCIENTIFIC AG, Villigen (CH)

(72) Inventors: Gunther STEINFELD, Waedenswil (CH); Harald NIEBEL, Oberkochen (DE); Christiaan VAN DEN BERG, ‘s-Gravenzande (NL); Alexander VAN VEEN, Den Haag (NL); Tomi TUOHIMAA, Stockholm (SE)

(21) Appl. No.: 18/683,071

(22) PCT Filed: Aug. 11, 2022
(86) PCT No.: PCT/EP2022/072504

§ 371 Date: Feb. 12, 2024

(30) Foreign Application Priority Data
Aug. 13, 2021 (EP) 21191210.0

(51) Int. Cl. H01J 37/21; H01J 37/14; H01J 37/147; H01J 37/153; H01J 37/26; H01J 37/295

(52) U.S. Cl. CPC H01J 37/21; H01J 37/14; H01J 37/1474; H01J 37/153; H01J 37/265; H01J 37/2955; H01J 2237/002; H01J 2237/0453; H01J 2237/1532

(57) ABSTRACT

A charged-particle beam device for charged-particle crystallography of a crystalline sample comprises a charged-particle source for generating a charged-particle beam to be radiated onto a sample and a charged-particle-optical system downstream the charged-particle source, which is configured to form in a diffraction mode a substantially parallel charged-particle beam at a predefined sample position and in an imaging mode a focused charged-particle beam having a focus at the predefined sample position. The charged-particle-optical system comprises a charged-particle zoom lens system consisting of a first magnetic lens, a second magnetic lens downstream the first magnetic lens and a third magnetic lens downstream the second magnetic lens, wherein at least the second magnetic lens, preferably each one of the first, the second and the third magnetic lens has a variable focal length. The charged-particle-optical system further comprises a single beam limiting aperture with a fixed aperture diameter arranged at a fixed position between the second magnetic lens and the third magnetic lens for limiting the diameter of the charged-particle beam at the sample position. The charged-particle-optical system is configured such that the diameter of the charged-particle beam at the sample position is in a range between 100 nanometer and 1000 nanometer, in particular between 220 nanometer and 250 nanometer, in the diffraction mode, and in a range between 10 nanometer and 200 nanometer in the imaging mode.

### FIELD OF THE INVENTION

The invention relates to a charged-particle beam device, in particular a diffractometer, for diffraction analysis, e.g. for charged-particle-crystallography of crystalline samples, comprising a charged-particle source for generating a charged-particle beam to be radiated onto a sample and a charged-particle-optical system downstream the charged-particle source.

### BACKGROUND ART

Crystallography is an essential technology in most fields of chemistry, in particular for structure determination of crystalline samples. For many decades, X-ray diffraction analysis has been the main technology for structure determination. However, X-ray diffraction analysis requires large and well-ordered crystals to obtain reflections from diffracted beams of significant intensity required for sufficient data collection. For analyzing smaller samples, in particular those which are difficult to be grown to a sufficiently large size, it has been proposed to use charged-particles, such as electrons, for structure determination. In contrast to X-ray diffraction, charged-particle diffraction imposes virtually no lower size limit to the crystal. For example, using a beam of accelerated electrons allows for recording diffraction patterns of nano-crystalline samples having a diameter of less than one micrometer down to several nanometers which correspond to only a few repeating units of crystal building blocks. In principle, all types of charged-particle beams can be used. A predominant example for structure using charged-particle beams is electron microscopy and electron diffractometry.

Devices primarily designed for diffraction analysis are rather rare. Therefore, electron diffraction analysis is usually performed in standard electron microscopes, especially transmission electron microscopes (TEM), since the basic technical components of electron diffractometers and transmission electron microscopes (TEM) are the same.

For nano-crystallography, i.e. for electron diffraction experiments used to determine the molecular structure of crystalline samples the workflow is such that first standard electron microscopy imaging techniques, are used to take a series of pictures—from overviews to strongly magnified ones—in order to identify a specific sample or particle which the diffraction experiment is to be performed on. However, the use of standard TEM imaging techniques with a large sized electron beam at the position of the plane, where the sample is located, may introduce a significant amount of radiation into the sample. In particular, the large sized electron beam illuminates all particles on a grid quite homogenously, independently from the chosen field of view, and will easily deteriorate or even destroy the sample. This problem particularly arises, when samples of sensitive material, such as organic or biological samples, have to be analyzed. Then, the timeframe for the overall analysis is limited, and the exposure of the sample to vacuum and electron radiation has to be minimized.

To reduce the amount of radiation, it is possible to use scanning transmission electron microscopy (STEM) techniques employing an electron beam with a reduced size at the position of the plane where the sample is located. This way, the amount of radiation, the sample is exposed to, can be reduced. Therefore, this approach yields significant advantages. However, the STEM mode and the diffraction mode require a different adjustment of the optical system. The readjustment process requires some time and a significant experience by the operator. The required time for the readjustment may cause a sensitive sample to reach or pass a critical level of deterioration, so that no sensible diffraction analysis can be performed anymore.

It is therefore an object of the invention to provide a charged-particle beam device, in particular a diffractometer, for diffraction analysis, e.g. for charged-particle-crystallography of crystalline samples, comprising a charged-particle source for generating a charged-particle beam to be irradiated onto a sample and a charged-particle-optical system downstream of the charged-particle source that is improved over such devices known in the state of the art.

### SUMMARY

According to the invention, there is provided a charged-particle beam device, in particular a diffractometer, for diffraction analysis, e.g. for charged-particle-crystallography of crystalline samples, which comprises a charged-particle source for generating a charged-particle beam to be radiated onto a sample and a charged-particle-optical system downstream the charged-particle source. The charged-particle beam device is configured to be operable in at least two modes, a diffraction mode and in an imaging mode. In the diffraction mode, the charged-particle beam device is configured to form a substantially parallel charged-particle beam at a predefined sample position. In the imaging mode, the charged-particle beam device is configured to form a focused charged-particle beam having a focus at the predefined sample position. According to the invention, the charged-particle-optical system comprises:
a charged-particle zoom lens system consisting of a first magnetic lens, a second magnetic lens downstream the first magnetic lens and a third magnetic lens downstream the second magnetic lens, wherein at least the second magnetic lens, preferably each one of the first, the second and the third magnetic lens has a variable focal length,
a single beam limiting aperture with a fixed aperture diameter arranged at a fixed position between the second magnetic lens and the third magnetic lens for limiting the diameter of the charged-particle beam at the sample position.

The charged-particle-optical system is configured such that the diameter of the charged-particle beam at the sample position is in a range between 100 nanometer and 1000 nanometer, in particular between 220 nanometer and 250 nanometer, in the diffraction mode, and in a range between 10 nanometer and 200 nanometer in the imaging mode.

According to the invention, it has been found that a fast and reliable switching between an imaging mode and a diffraction mode, whilst still having a good analyzing quality for each mode, can be realized by an optical system compromising a single beam limiting aperture with a fixed aperture diameter arranged at a fixed position and a charged-particle zoom lens system consisting of three magnetic lenses only, i.e. a first magnetic lens, a second magnetic lens and a third magnetic lens. When using such an optical system, no time-consuming adjustment is necessary anymore when changing between the two modes. In particular, the device is capable of switching between the imaging mode and the diffraction by merely changing the variable focal length of the second magnetic lens, which may be achieved purely electrically, in particular by applying a different electric current.

In other words, the charged-particle beam device according to the present invention can be used in and/or can be switched between a diffraction mode and an imaging mode (and vice versa) without effectuating mechanical movements, in particular mechanical movements of parts that are arranged within a vacuum, but simply by changing electrical parameters that are applied to the respective devices, in particular to the first magnetic lens, the second magnetic lens and/or the third magnetic lens, even more particularly to the at least second magnetic lens.

Furthermore, since the single beam limiting aperture has a fixed aperture diameter and is placed at a fixed position between the second magnetic lens and the third magnetic lens, the design and the manufacture of the charged-particle beam device is easier and less expensive. Due to the fixed aperture size and position, the charged-particle beam device is also more reliable as compared to devices employing beam limiting apertures with a variable aperture size or position, as they are used with some present-day devices.

Though, in principle, no time-consuming adjustment is necessary anymore when changing between the two modes, it might be possible to perform some typically minor adjustments after switching between the two modes. For example, when switching from a diffraction mode into an imaging mode, it may be necessary to focus the focal point of the charged-particle beam in the imaging mode. However, this is quite simple as compared to present-day charged-particle beam devices. The first mode to start with may be either the diffraction mode or the imaging mode. Accordingly, the consecutive mode will be the imaging mode or the diffraction mode, respectively. Of course, it is also possible to change between the imaging mode and the diffraction mode (or vice versa) several times. The changeover may be effectuated by the operator. It is also possible that some automatization will be used, so that switching between the modes will be effectuated by a computer device or the like.

The focal point of the charged-particle beam may be at the predefined sample position, so that a high imaging quality may be achieved. However, it is additionally or alternatively possible to use a slight offset of the focal point with respect to the predefined sample position. Such a slight off-focal setting might be advantageous for finding a suitable area/volume within the sample, where the thus identified suitable area/volume will be subsequently used for a following diffraction mode analysis, as an example. This way, a time-consuming scanning of the sample can be advantageously shortened. In particular, in case a very sensitive sample and/or a sample with a short lifetime is used, a fast identification of the area of the sample to be further analyzed may improve the quality of the diffraction measurement significantly, or may even make such a measurement possible at all.

Preferably, not only the second magnetic lens, but also at least one of the first magnetic lens and the third magnetic lens, in particular each of the three magnetic lenses has a variable focal length. Advantageously, this may allow to adjust the optical system more easily, for example, to adjust the focal point of the charged-particle beam in the imaging mode, as discussed above.

In particular, the first magnetic lens may be configured such that the focal length of the first magnetic lens is in a range between 10 mm and 30 mm, in particular at 20 mm, in the diffraction mode; and is in the range between 20 mm and 40 mm, in particular 29 mm, in the imaging mode. These design parameters have proven to be advantageous for the presently suggested design. However, a lower limit in the diffraction mode of 5 mm, 15 mm, 20 mm and 25 mm and/or an upper limit in the diffraction mode of 25 mm, 35 mm, 40 mm or 45 mm can be employed as well. In the imaging mode, a lower limit of 10 mm, 15 mm, 25 mm and an upper limit of 30 mm, 35 mm, 45 mm and 55 mm may be used as well.

Furthermore, the second magnetic lens may be configured such that the focal length of the second magnetic lens is in a range between 90 mm and 110 mm, in particular 103 millimeter, in the diffraction mode, and in a range between 30 millimeter and 40 millimeter, in particular 35 millimeter, in the imaging mode. These design parameters have proven to be advantageous for the presently suggested design. However, a lower limit in the diffraction mode of 50 mm, 60 mm, 70 mm, 80 mm or 100 mm and/or an upper limit in the diffraction mode of 120 mm, 150 mm or 200 mm can be employed as well. In the imaging mode, a lower limit of 10 mm, 15 mm, 20 mm or 25 mm and an upper limit of 45 mm, 50 mm, 60 mm and 70 mm may be used as well.

Likewise, the third magnetic lens may be configured such that the focal length of the third magnetic lens is in a range between 80 millimeter and 100 millimeter, in particular 91 millimeter, in the diffraction mode, and in a range between 20 millimeter and 30 millimeter, in particular 25 millimeter, in the imaging mode. These design parameters have proven to be advantageous for the presently suggested design. However, a lower limit in the diffraction mode of 50 mm, 60 mm, 70 mm, or 90 mm and/or an upper limit in the diffraction mode of 110 mm, 120 mm, 150 mm or 200 mm can be employed as well. In the imaging mode, a lower limit of 5 mm, 10 mm, or 15 mm and an upper limit of 35 mm, 40 mm, 45 mm, 50 mm, 60 mm and 70 mm may be used as well.

In particular, it is suggested that in the charged-particle beam device the design of the first magnetic lens may be identical to design the second magnetic lens. This way, the design of the resulting charged-particle beam device can be simplified and/or be more cost efficient, whilst still having a good imaging quality. Vice versa, it is also possible that the design of the first magnetic lens is different from design the second magnetic lens.

Preferably, the charged-particle-optical system comprises no further magnetic lens or lens system other than the charged-particle zoom lens system consisting of the first, second and third magnetic lens. That is, there are no further magnetic lenses between the charged-particle source and the predefined sample position. In other words, the charged-particle zoom lens system is a three-lens system. That is, the charged-particle zoom lens system is the sole magnetic lens system between the charged-particle source and the predefined sample position, that is, the first, second and third magnetic lens are the sole magnetic lenses between the charged-particle source and the predefined sample position. This way, the complexity of the charged-particle beam device can be reduced, resulting in a more robust and more cost-efficient design with a possibly increased lifetime due to the simpler and less complex design.

As used herein, the relative arrangement of “downstream” is meant to be seen in the direction of the charged-particle beam that is generated/released by the charged-particle source. In principle, all types of magnetic lenses that are used in the present field of technology can be used as a magnetic lens with a fixed focal length and/or as a magnetic lens with a variable focal length. Thus, the charged-particle beam device is easy, less expensive and faster to be manufactured, since the construction may be based on a variety of readily available devices that are commercially available.

The above said also applies to the charged-particle source for generating the charged-particle beam to be irradiated onto the sample and/or possibly applies to other devices, means, parts and/or constructions that are used for the presently suggested charged-particle beam device, in particular including the modifications that will be elaborated in the following in more detail.

Preferably, the charged-particle beam is an electron beam. Accordingly, the charged-particle source preferably is an electron source. As compared to x-ray diffraction, the interaction between electrons and the atoms of the crystalline sample is much larger, allowing to observe diffraction patterns of crystals having a diameter of the less than one micrometer down to several nanometers. In principle, it is also possible to use different charged particles, like protons, helium atom ions/helium nuclei or the like.

Preferably, the electron source is configured to generate an electron beam having an energy in a range of 60 keV to 300 keV, with a tolerance in a range of +0.7 keV to +1.5 keV. For example, the electron source may be configured to generate an electron beam of 200 keV±1.2 keV. Likewise, the electron source may be configured to generate an electron beam of 160 keV having a ripple of 80 eV peak-to peak. The electron source may be configured to be operated at one or more constant acceleration voltages. Alternatively, the electron source may be configured to generate a beam of electrons having a selectable energy.

As defined above, the charged-particle beam device is configured to form a substantially parallel charged-particle beam at a predefined sample position in the diffraction mode. Used herein, the term “substantially parallel charged particle beam” refers to a charged particle beam having a convergence angle less than or equal to an upper limit of 0.5°. However, different, in particular much smaller upper limits of the convergence angle may be more preferable, like 0.1°, in particular 0.05°, more particularly 0.025°, preferably 0.01°. As used herein, the convergence angle refers to the half opening angle of the charged particle beam.

According to the invention, the charged-particle-optical system is configured in a way that the diameter of the charged-particle beam at the sample position is in a range between 100 nm and 1000 nm, in particular between 200 nm and 800 nm, more particularly between 200 nm and 750 nm, preferably between 200 nm and 500 nm or between 200 nm and 400 nm or between 200 nm and 300 nm or between 300 nm and 500 nm or between 300 nm and 400 nm or between 220 nm and 250 nm in the diffraction mode. In the (scanning or STEM) imaging mode, the diameter of the charged-particle beam at the same position is typically in a range between 10 nm and 200 nm, in particular between 10 nm and 150 nm or between 30 nm and 150 nm, preferably between 10 nm and 80 nm, more preferably between 10 nm and 40 nm or between 20 nm and 40 nm. It is to be understood that the lower limit for the charged-particle beam in the diffraction mode may be 80 nm, 120 nm, 150 nm, and 200 nm as well, while the upper limit may be 270 nm, 300 nm, 350 nm, 400 nm, 500 nm, 600 nm, 700 nm, 800 nm and 900 nm as well. Likewise, the diameter of the charge-particle beam in the (scanning or STEM) imaging mode may have a lower limit of 5 nm, 10 nm, 15 nm, 20 nm, 30 nm, 40 nm, 50 nm and 75 nm as well, while its upper limit may be 40 nm, 60 nm, 80 nm, 100 nm, 120 nm, 150 nm and 175 nm as well. It has been found that the described ranges, lower limits and/or upper limits are particularly advantageous for the charged-particle beam device at the present invention while maintaining good imaging properties of the charged-particle beam device.

The single beam limiting aperture with the fixed aperture diameter may be a plate with an opening therein. As used herein, “thin” relates to the material that is used for the plate and/or to the charged-particles that are used, as well as to the energy of the charged-particle beam that is used. Further, it should be kept in mind that the single beam limiting aperture (and possibly other parts of the charged-particle beam device) is (are) arranged within a vacuum, so that the charged-particle beam will not be diverted or dampened by the gas to be passed through (in case there is no vacuum).

Therefore, in case of electron beams with an electron beam energy a plate made of steel with a thickness in the order of 1 mm, 2 mm or 3 mm may be used. The single beam limiting aperture may also be made of gold, platinum or molybdenum.

With respect to the dimensions of the optical system it has been found that the aperture diameter preferably is chosen large enough to avoid an obstruction of the aperture. The larger the aperture size, the larger the overall length of the optical system, i.e. the distance between the virtual position of the charged-particle source and the predefined sample position.

According to one specific embodiment of the present invention, the fixed aperture diameter of the beam limiting aperture may be in a range between 30 μm and 60 μm, in particular 35 μm and 45 μm, whereas a distance between the virtual position of the charged-particle source and the predefined sample position may be in a range between 600 mm and 800 mm, in particular between 650 mm and 750 mm or between 650 mm and 700 mm. Advantageously, an aperture diameter in a range between 30 μm and 60 μm, in particular 35 μm and 45 μm may be beneficial to avoid an obstruction of the aperture. Smaller aperture diameters are all possible to reduce the beam intensity/dose at the sample position. Accordingly, the fixed aperture diameter of the beam limiting aperture may in general be in a range between 1 μm and 60 μm, in particular between 2 μm and 60 μm or between 5 μm and 60 μm, in particular between 10 μm and 45 μm or between 5 μm and 10 μm, while having a distance between the virtual position of the charged-particle source and the predefined sample position in a range between 600 mm and 800 mm, in particular between 650 mm and 750 mm or between 650 mm and 700 mm.

The larger the aperture size, the larger the overall length of the optical system, i.e. the distance between the virtual position of the charged-particle source and the predefined sample position. Accordingly, a more compact design of the charged-particle beam device may be achieved by a selecting smaller aperture size. Hence, according to another specific embodiment of the present invention the beam limiting aperture may have a fixed aperture diameter in a range between 1 μm and 10 μm, in particular between 2 μm and 10 μm or between 5 μm and 10 μm, for example, 1 μm or 2 μm or 5 μm, whereas a distance between a virtual position of the charged-particle source and the predefined sample position may be in the range between 300 mm and 500 mm, in particular between the 350 mm and 400 mm.

Furthermore, it is suggested that the charged-particle-optical system preferably comprises a first deflector system that is arranged between the first magnetic lens and the second magnetic lens and configured to two-dimensionally scan the charge-particle beam in order to control the angle of the charge-particle beam at the beam limiting aperture such that the charged-particle beam passes through an optical axis of the third magnetic lens. Advantageously, the first deflector system facilitates the initial alignment of the optical system. In particular, a pivot point of the first deflector system may be chosen such that it is at the optical axis in the plane of the beam limiting aperture. The first deflector system may comprise a first beam deflector and a second beam deflector. It has been found that when using a double deflector arrangement with two beam deflectors (or a multiple deflector arrangement with three, four, five, six, seven or eight beam deflectors), the overall performance of the charged-particle beam device can be increased with usually no or little additional cost and/or without significant additional complexity.

The charged-particle-optical system may further comprise a second deflector system that is arranged between the beam limiting aperture and the third magnetic lens for two-dimensionally scanning the charged-particle beam at the predefined sample position. Advantageously, this allows for operating the charged-particle beam device in a scanning imaging mode which is essentially equivalent to the scanning imaging mode of a scanning transmission electron microscope (STEM) or a raster-scanning transmission electron microscope (RSTEM). It is to be noted that the scanning or raster-scanning can be still realized with a beam limiting aperture having fixed aperture size and a fixed position. Preferably, the pivot point of the second deflector system is at the optical axis in a main plane of the third magnetic lens which facilitates the operational implementation of a scanning imaging mode. Like for the first deflector system, it is suggested that the second deflector system comprises at least two beam deflectors, in particular a third beam deflector and a fourth beam deflector.

According to another aspect of the invention, the charged-particle-optical system may further comprise a charged-particle stigmator arranged between the first deflector system and the second magnetic lens to correct for astigmatism. It has been found that the presently suggested arrangement and the position of the charged-particle stigmator is particularly suitable for increasing the imaging quality of the charged-particle beam device. It is to be noted that charged-particle stigmators that are well known in the present field of technology. In particular, charged-particle stigmators that are commercially available can be used for the presently suggested design.

Preferably, the charged-particle beam device comprises a scraping aperture that is arranged between the charged-particle source and the first magnetic lens. The scraping aperture serves to scrap of electron outside a preferred divergence cone. Thus, imaging errors due to a divergence (non-parallelism) of the charged-particle beam in the diffraction mode and/or when operating in the imaging mode, the smearing of the focal point for differently angled incident beam paths, when seen in the direction of the propagation of the charged-particle beam, can be reduced. This way, the imaging quality of the resulting charged-particle device can be increased even further.

In particular when using a high energy electron beam, the charged-particle beam device preferably comprises a cooling equipment for cooling the scraping aperture. This way, the lifetime of the charged-particle beam device can be increased, since the impact of the continuous flux of accelerated charged particles onto the scraping aperture can lead to a substantial temperature increase that might prove to be problematic for the scraping aperture or parts nearby. Furthermore, such a temperature increase can lead to diffusion effects that in turn might lower the quality of the vacuum.

### BRIEF DESCRIPTION OF THE DRAWINGS

FIG. 1: schematically shows the principal setup of a charged-particle beam device according to an exemplary embodiment of the present invention; and

FIG. 2: shows further details of the charged-particle beam device according to FIG. 1.

### DETAILED DESCRIPTION OF EMBODIMENTS

The subject matter is now described with reference to the drawings, wherein like reference numerals are used to refer to like elements throughout.

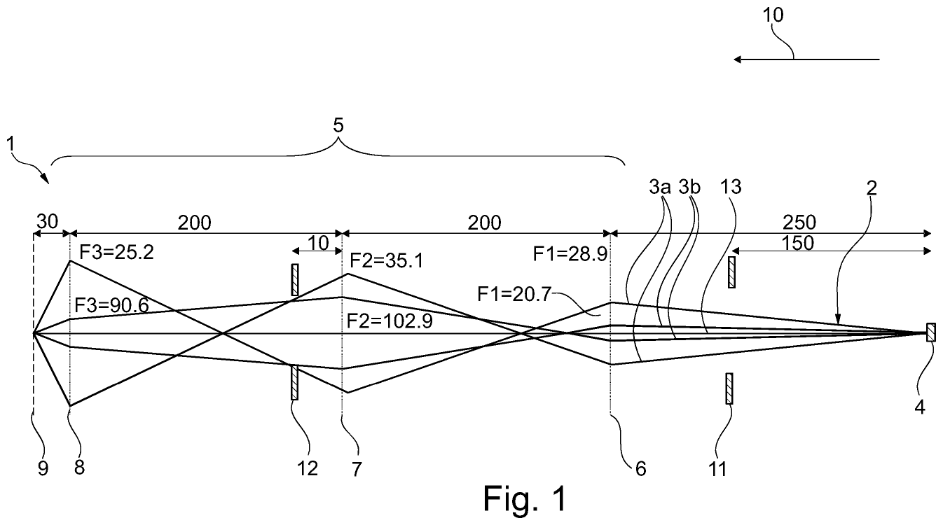

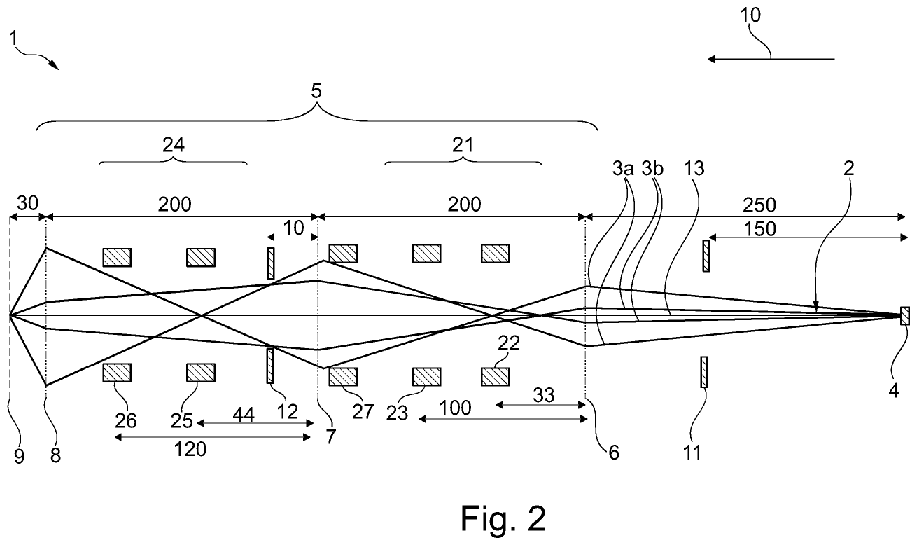

FIG. 1 schematically shows the principal setup of a charged-particle beam device 1 according to an exemplary embodiment of the present invention. In the present embodiment, the charged-particle beam device 1 is designed as an electron beam device that uses a beam of electrons with a kinetic energy of about 160 keV as a charged-particle beam 2. All numbers (including those which are presented in the following) are valid for the embodiment of a charge-particle beam device 1, as shown in FIG. 1 (and consequently in FIG. 2). It is to be understood that different numbers can be used as well, depending on the exact requirements.

A charged-particle source 4, here an electron gun, is used for generating the charged-particle beam 2 of electrons. Due to the nature of the electron gun, the charged-particle beam 2 is divergent when escaping from the electron gun. That is, the charged-particle source 4 emits a roughly cone-shaped charged-particle beam 2. For reference, a center axis 13 of the charge-particle beam device 1 (optical axis) is also indicated in FIG. 1.

In order to stop and remove those parts of the charged-particle beam 2 that are too divergent, when escaping from the charged-particle source 4, the beam device 1 comprises a scraping aperture 11 which is arranged downstream the charged-particle source 4 as seen on the propagating direction 10 (indicated by an arrow in FIG. 1) of the charged-particle beam 2. Preferably, the scraping aperture 11 is cooled by a cooling equipment (not shown) in order to remove heat from the scraping aperture 11 that is generated by dissipating the impact energy of the 160 keV electrons impacting the scraping aperture 11.

Downstream the scraping aperture 11, the charged-particle beam 2 is passes through a charged-particle-optical system which comprises a beam-limiting aperture 12 and a charged-particle zoom lens system 5. The lens system 5 consists of three magnetic lenses, namely first magnetic lens 6, a second magnetic lens 7 and a third magnetic lens 8, where the numbering of the magnetic lenses 6, 7, 8 is chosen according to the direction of the charged particles of charged-particle beam 2. Each of the three magnetic lenses has a variable focal length which can be varied purely electrically, in particular by applying a different electric current. The beam-limiting aperture 12 is arranged between the second magnetic lens 7 and the third magnetic lens 8. It is to be noted that both the scraping aperture 11 and the beam limiting aperture 12 are designed with a fixed aperture diameter, and are placed at a fixed position, respectively. In particular, the scraping aperture 11 is placed 150 mm downstream of the charged-particle source 4 and 100 mm upstream of the first magnetic lens 6, while the beam limiting aperture 12 is placed 10 mm downstream of the second magnetic lens 7 and 190 mm upstream of third magnetic lens 8. The fixed aperture diameter of the beam limiting a picture 12 is presently chosen to be 40 μm.

The charged-particle-optical system of the beam device 1 according to the present embodiment is configured to be selectively operated in two modes, namely, an imaging mode and a diffraction. In the imaging mode the charged-particle-optical system is configured to form in a diffraction mode a substantially parallel charged-particle beam 2 at a predefined sample position 9, whereas in the imaging mode the charged-particle-optical system is configured to form a focused charged-particle beam 2 having a focus at the predefined sample position 9. This is illustrated in FIG. 1, where lines 3a show the beam path in the imaging mode, and lines 3b show the beam path in the diffraction mode. It is to be noted that “substantially parallel” does mean in the presently depicted example that the charged-particle beam has an angle of divergence of about 5° at the predefined sample position 9.

At the predefined sample position 9, a sample support may be placed, onto which a sample to be analyzed may be placed. Primarily, charged-particle-optical system according to the present invention is designed to analyze the sample in the diffraction mode. In particular, the device 1 is designed for charged-particle crystallography of crystalline samples. In contrast, the imaging mode is (only) used to take a series of overview pictures in order to identify a specific sample or particle which the diffraction experiment is to be performed on.

Advantageously, the device is capable of switching between the imaging mode and the diffraction may merely changing the variable focal length of the second magnetic lens, which may be achieved purely electrically without effectuating mechanical movements of any components.

The distance between the charged-particle source 4 and the first magnetic lens 6 is 250 mm, the distance between first magnetic lens 6 and second magnetic lens 7 is 200 mm, while the distance between second magnetic lens 7 and third magnetic lens 8 is 200 mm. The predefined sample position 9 is located 30 mm downstream of third magnetic lens 8. Therefore, when adding the distances together, the distance between the charged-particle source 4 and the predefined sample position 9 is 680 mm.

In the present embodiment, in the imaging mode (see exemplary charged-particle path of the imaging mode 3a), the focal length F1 of first magnetic lens 6 is set to 28.9 mm, the focal length F2 of second magnetic lens 7 is set to 35.1 mm, while the focal length F3 of third magnetic lens 8 is set to 25.2 mm. This will result in a convergent charged-particle beam 2 at the predefined sample position 9 in a way that the diameter of the charged-particle beam 2 at the sample position 9 is about 50 nm in the imaging mode (see exemplary charged-particle path in the imaging mode 3a).

In the diffraction mode, in which the charged-particle beam 2 is substantially parallel at the predefined sample position 9 (with a divergence angle of about) 5°, the focal length F1 of the first magnetic lens 6 is set to 20.7 mm, the focal length F2 of the second magnetic lens 7 is set to 102.9 mm, and the focal length F3 of the third magnetic lens 8 is set to 90.6 mm. This results in a diameter of the charged-particle beam 2 at the predefined sample position 9 of approximately 400 nm.

FIG. 2, shows further details of the charged-particle beam device 1 according to FIG. 1, some additional parts are used. For simplicity, for similar or even identical parts the reference numerals that were used in FIG. 1 will be continued to be used in FIG. 2. In addition to FIG. 1, FIG. 2 shows a first deflector system 21, a second deflector system 24 and a charged-particle stigmator 27.

The first deflector system 21 is arranged between the first magnetic lens 6 and the second magnetic lens 7. The first deflector system 21 comprises two beam deflectors 22, 23, namely a first beam deflector 22 and a second beam deflector 23. The first beam deflector 22 of the first deflector system 21 is placed 33 mm downstream of the first magnetic lens 6, while second beam deflector 23 of the first deflector system 21 is placed 100 mm downstream (i.e. in the propagation direction 10) of the first magnetic lens 6. Both, the first beam deflector system 22 and the second beam deflector 23 form a double deflector allowing for two-dimensionally scanning the charged-particle beam 2 in a plane perpendicular to the center axis 13 of the charge-particle beam device 1 in order to control the angle of the charged-particle beam 2 at the beam limiting aperture 12 such that the charged-particle beam 2 passes through the optical axis 13 at the position of the third magnetic lens 8. In particular, the pivot point of the first deflector system 21 is chosen to be at the optical axis 13 in the plane of/at the position of the beam limiting aperture 12.

The second deflector system 24 is arranged between the second magnetic lens 7 and the third magnetic lens 8, more particular between the beam limiting aperture 12 and the third magnetic lens 8. Similar to the first deflector system 21, the second deflector system 24 comprises two beam deflectors 25, 26, namely, a third beam deflector 25 that is arranged 44 mm downstream of the second magnetic lens 7, and a fourth beam deflector 26 that is arranged 120 mm downstream of the second magnetic lens 7.

The second deflector system 24 is configured and arranged to two-dimensionally scan the charged-particle beam 2 in a plane perpendicular to the center axis 13 at the predefined sample position 9. The pivot point of the second deflector system 24 is chosen such as to be at the optical axis 13 in the main plane of the third magnetic lens 8. Advantageously, the second deflector system 24 allows for operating the charged-particle beam device 1 in a scanning imaging mode which is essentially equivalent to the scanning imaging mode of a scanning transmission electron microscope (STEM) or a raster-scanning transmission electron microscope (RSTEM).

Usually, the second deflection system 24 will only be active (if at all), if the charge-particle beam device 20 is operated in a scanning imaging mode, in which the exemplary charged-particle path of the imaging mode 3a is the active one. However, the first deflector system 21 might be active in both modes, i.e. in the diffraction mode as well as in the imaging mode.

As can be further seen in FIG. 2, the charged-particle stigmator is arranged between the first magnetic lens 6 and the second magnetic lens 7, more particularly between the first deflector system 21 and the second magnetic lens. Using the charged-particle stigmator 27, an astigmatism of the charged-particle beam 2 can be corrected. This may apply to the imaging mode (exemplary charged-particle path 3a), the diffraction mode (exemplary charged-particle path 3b), or both.

1. A charged-particle beam device for charged-particle crystallography of crystalline samples, comprising a charged-particle source for generating a charged-particle beam to be radiated onto a sample and a charged-particle-optical system downstream the charged-particle source, which is configured to form in a diffraction mode a substantially parallel charged-particle beam at a predefined sample position and in an imaging mode a focused charged-particle beam having a focus at the predefined sample position, the charged-particle-optical system comprising:
a charged-particle zoom lens system consisting of a first magnetic lens, a second magnetic lens downstream the first magnetic lens and a third magnetic lens downstream the second magnetic lens, wherein at least the second magnetic lens, preferably each one of the first, the second and the third magnetic lens has a variable focal length,
a single beam limiting aperture with a fixed aperture diameter arranged at a fixed position between the second magnetic lens and the third magnetic lens for limiting the diameter of the charged-particle beam at the sample position, wherein the charged-particle-optical system is configured such that the diameter of the charged-particle beam at the sample position is in a range between 100 nanometer and 1000 nanometer, in particular between 220 nanometer and 250 nanometer, in the diffraction mode, and in a range between 10 nanometer and 200 nanometer in the imaging mode.

2. The charged-particle beam device according to claim 1, wherein the beam limiting aperture has a fixed aperture diameter in a range between 30 micrometer and 60 micrometer, in particular between 35 micrometer and 45 micrometer, and wherein a distance between a virtual position of the charged-particle source and the predefined sample position is in a range between 600 millimeter and 800 millimeter, in particular between 650 millimeter and 700 millimeter.

3. The charged-particle beam device according to claim 1, wherein the beam limiting aperture has a fixed aperture diameter in a range between 5 micrometer and 10 micrometer, and wherein a distance between a virtual position of the charged-particle source and the predefined sample position is in a range between 300 millimeter and 500 millimeter, in particular between 350 millimeter and 400 millimeter.

4. The charged-particle beam device according to claim 1, wherein the beam limiting aperture has a fixed aperture diameter in a range between 5 micrometer and 10 micrometer, and wherein a distance between a virtual position of the charged-particle source and the predefined sample position is in a range between 600 millimeter and 800 millimeter, in particular between 650 millimeter and 700 millimeter.

5. The charged-particle beam device according to claim 1, wherein the charged-particle-optical system further comprises a first deflector system arranged between the first magnetic lens and the second magnetic lens for two-dimensionally scanning the charged-particle beam to control the angle of the charged-particle beam at the beam limiting aperture such that the charged-particle beam passes through an optical axis of the third magnetic lens.

6. The charged-particle beam device according to claim 5, wherein a pivot point of the first deflector system is at the optical axis of the beam limiting aperture.

7. The charged-particle beam device according to claim 5, wherein the first deflector system comprises a first beam deflector and a second beam deflector.

8. The charged-particle beam device according to claim 1, wherein the charged-particle-optical system further comprises a second deflector system arranged between the beam limiting aperture and the third magnetic lens for two-dimensionally scanning the charged-particle beam at the predefined sample position.

9. The charged-particle beam device according to claim 8, wherein a pivot point of the second deflector system is at the optical axis in a main plane of the third magnetic lens.

10. The charged-particle beam device according to claim 8, wherein the second deflector system comprises a third beam deflector and a fourth beam deflector.

11. The charged-particle beam device according to claim 1, wherein the charged-particle-optical system further comprises a charged-particle stigmator arranged between the first deflector system and the second magnetic lens to correct for astigmatism.

12. The charged-particle beam device according to claim 1, further comprising a scraping aperture arranged between the charged-particle source and the first magnetic lens.

13. The charged-particle beam device according to claim 12, further comprising a cooling equipment for cooling the scraping aperture.

14. The charged-particle beam device according to claim 1, wherein a focal length of the first magnetic lens is in a range between 10 millimeter and 30 millimeter, in particular 20 millimeter, in the diffraction mode, and in a range between 20 millimeter and 40 millimeter, in particular 29 millimeter, in the imaging mode.

15. The charged-particle beam device according to claim 1, wherein a focal length of the second magnetic lens is in a range between 90 millimeter and 110 millimeter, in particular 103 millimeter, in the diffraction mode, and in a range between 30 millimeter and 40 millimeter, in particular 35 millimeter, in the imaging mode.

16. The charged-particle beam device according to claim 1, wherein a focal length of the third magnetic lens is in a range between 80 millimeter and 100 millimeter, in particular 91 millimeter, in the diffraction mode, and in a range between 20 millimeter and 30 millimeter, in particular 25 millimeter, in the imaging mode.
